(19) United States
(12) Patent Application Publication
(10) Pub. No.: US 2010/0027813 A1
(43) Pub. Date: Feb. 4, 2010

(54) SWITCHING AUDIO AMPLIFIER, DIGITAL SPEAKING DEVICE AND AUDIO AMPLIFICATION METHOD

(75) Inventor: Li-Te WU, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: FORTEMEDIA, INC., Cupertino, CA (US)

(21) Appl. No.: 12/183,239

(22) Filed: Jul. 31, 2008

(51) Int. Cl. H03F 21/00

(52) U.S. Cl. 381/120

(57) ABSTRACT

A switching audio amplifier adapted in a digital speaking device for driving a speaker is provided. An audio amplification method implemented for the switching audio amplifier is also provided. In the switching audio amplifier, a comparison stage compares an audio input signal with a saw-tooth signal to generate a Pulse Width Modulation (PWM) signal. A driver stage buffers the PWM signal to drive the speaker. A detector detects amplitude of the input signal to generate a control signal, and a saw-tooth generator adjusts a transition rate of the saw-tooth signal based on the control signal.

### BACKGROUND OF THE INVENTION

1. Field of the Invention

The invention relates to audio amplifiers, and in particular, to an adjustable saw-tooth generator for a class D audio amplifier.

2. Description of the Related Art

Audio playback technology is prevalent in portable digital devices such as a mobile phone, a multimedia player or a digital recorder. Audio amplifiers adapted in portable digital devices are required to have low power consumption while outputting high quality sounds. However, there is always a tradeoff therebetween.

FIG. 1 shows a conventional class D audio amplifier structure. In FIG. 1, a speaker 106 is driven by a first PWM signal #U and a second PWM signal #D respectively sent from a buffering stage comprising a first driver 104a and a second driver 104b. The first PWM signal #U and second PWM signal #D are respectively generated from a pair of comparators 102a and 102b based on an audio input signal V+ and a saw-tooth generate 108. The first comparator 102a compares the audio input signal V+ with a saw-tooth signal #S sent from the saw-tooth generate 108 to generate the first PWM signal #U. Concurrently, the second comparator 102b compares an inversion of the audio input signal V− with the saw-tooth signal #S to generate the second PWM signal #D. Automatically, the input audio signals V+ and V− are converted to Pulse Width Modulation (PWM) signals that represent varying duty cycles. Additionally, the speaker 106 functions as a capacitor cascaded with a resistor and an inductor, whereby the first PWM signal #U and second PWM signal #D are broadcasted as audio sounds.

As known, a class D audio amplifier can exhibit about 80% to 93% high power efficiency, because the first driver 104a and second driver 104b are biased either under the off region or triode region with very low turn-on resistance (about 0.2 ohm), thereby significantly extending battery life. However, sharp rising and falling PWM signals edges induce unwanted high frequency components and emit radiation to cause Electro-Magnetic Interference (EMI). Meanwhile, the U.S. Federal Communication Commission (FCC) strictly enforces low EMI requirement standards. There are various prior arts dedicated to resolving EMI issues so that FCC compliance can be met. For example, a Low Pass Filter (LPF) may be added to eliminate the high frequency components. The disadvantages of implementing an LPF however, are its large size and high costs. Some prior art suggests using an inherent Resistance-Capacitance (RC) constants in a speaker to produce an equivalent LPF, which is effective for large speaker devices such as those used in home theater systems. For other applications such as portable digital devices, however, speakers are required to be compact and the RC constants provided thereby are too low to filtrate out the high frequency components.

FIG. 2 shows frequency spectrum of a signal output from the speaker 106. The horizontal axis indicates frequency and the vertical axis indicates magnitude. The in-band signal 202 is the audio signal designated to be heard, operating at frequency w and having a magnitude m. There may be minor harmonic distortions 204 and 206 occurring at frequencies 2w and 3w. Furthermore, a pair of side lobes 212 respectively occur at frequencies 2x+w and 2x−w, where the 2x is a second order carrier frequency. The carrier frequency x is dependent on various factors including the LC constants in the digital speaking device 100 and a transition rate of the saw-tooth generate 108. FIG. 2 shows that an LPF curve 210 provided by the inherent LC constants of the speaker 106 can not effectively filtrate out the side lobes 212. Thus, the pair of side lobes 212 has subsequently identical magnitudes to that of the in-band signal 202, and the EMI induced thereby may significantly influence the operation of the circuit. Although the side lobes 212 can be shifted right toward the effective filtration region of the LPF curve 210 by increasing the transition rate of the saw-tooth generate 108, power efficiency would decrease as a tradeoff. Hence, it is desirable to provide an audio amplifier having low power consumption while outputting high quality sounds.

### BRIEF SUMMARY OF THE INVENTION

A switching audio amplifier is provided, adapted in a digital speaking device for driving a speaker. In the switching audio amplifier, a comparison stage compares an audio input signal with a saw-tooth signal to generate a Pulse Width Modulation (PWM) signal. A driver stage buffers the PWM signal to drive the speaker. A detector detects amplitude of the input signal to generate a control signal, and a saw-tooth generator adjusts a transition rate of the saw-tooth signal based on the control signal.

In the comparison stage, a first comparator compares the audio input signal with the saw-tooth signal to generate a first PWM signal. A second comparator compares an inversion of the audio input signal with the saw-tooth signal to generate a second PWM signal.

In the driver stage, a first driver receives the first PWM signal to drive a first end of the speaker, and a second driver receives the second PWM signal to drive a second end of the speaker.

The relationship between the transition rate of the saw-tooth signal and the amplitude of the audio input signal may be a monotonic increasing function. Alternatively, the relationship between the transition rate of the saw-tooth signal and the amplitude of the audio input signal may be a stepwise increasing function.

In the detector, a diode has its P end coupled to the audio input signal, and an N end coupled to a first node. A resistor and a capacitor are cascaded in parallel between the first node and a voltage ground. An ADC generates the control signal based on a voltage level of the first node.

In an embodiment of the saw-tooth generator, a programmable current source generates a current based on a control signal and a difference signal. A capacitor is coupled to the programmable current source and the voltage ground, driven by the current to generate the saw-tooth signal. A reference generator generates a reference value based on the difference signal, and the difference signal is generated by an operational amplifier comparing the saw-tooth signal and the reference value.

The reference generator outputs a positive reference value when the difference signal is positive. Conversely, the reference generator outputs a negative reference value when the difference signal is negative. Meanwhile, the programmable current source is switched to a first mode when the difference signal is positive, such that the current charges the capacitor to generate the saw-tooth signal. When the difference signal is negative, the programmable current source is switched to a second mode, such that the capacitor discharges to generate the saw-tooth signal.

An audio amplification method implemented for the described switching audio amplifier is also provided. An audio input signal is first provided. Amplitude of the audio input signal is then detected. A saw-tooth signal is generated, with its transition rate determined based on the amplitude of the audio signal. The audio input signal is compared with the saw-tooth signal to generate a Pulse Width Modulation (PWM) signal. The speaker is driven by the PWM signal to output audio sounds. A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional class D audio amplifier structure;

FIG. 2 shows frequency spectrum of a signal output from the speaker 106;

FIG. 3 shows an embodiment of a digital speaking device 300 according to the invention;

FIGS. 4a and 4b show embodiments of transition functions between signal amplitude A_{IN} of an input audio signal V+ and transition rate F_{SAW} of a saw-tooth signal #S;

FIG. 5a shows an embodiment of a detector 310;

FIG. 5b shows an embodiment of a saw-tooth generator 320;

FIG. 6 shows waveforms of a saw-tooth signal #S, and audio input signals V+ and V− according to the invention;

FIG. 7 shows frequency spectrum of a signal output from the speaker 106 according to the invention; and

FIG. 8 is a flowchart of an audio amplification method according to the invention.

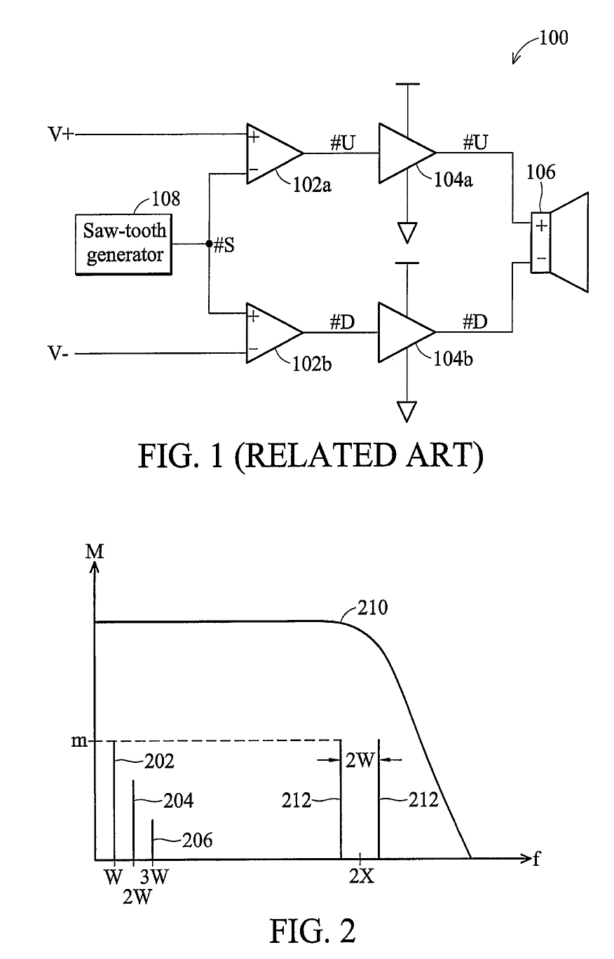

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

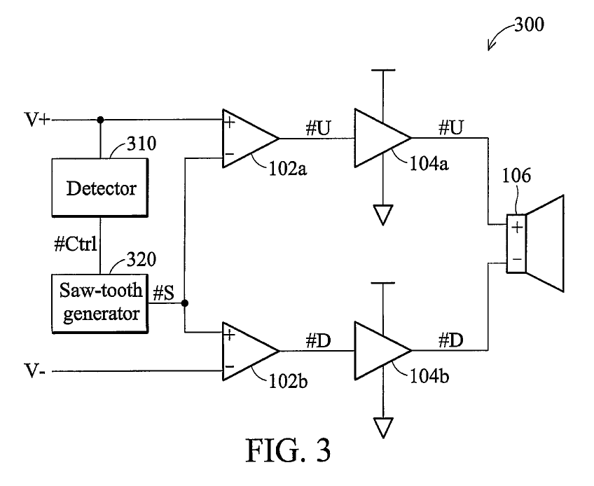

FIG. 3 shows an embodiment of a digital speaking device 300 according to the invention. The digital speaking device typically comprises a switching audio amplifier and a speaker 106 driven by the switching audio amplifier. In the embodiment, the switching audio amplifier is a modified version of a class D architecture. A first comparator 102a and a second comparator 102b form a comparison stage, converting an audio input signal V+ into a Pulse Width Modulation (PWM) signal based on a saw-tooth signal #S. Specifically, the first comparator 102a compares the audio input signal V+ with the saw-tooth signal #S to generate a first PWM signal #U, and the second comparator 102b compares an inversion of the audio input signal V− with the saw-tooth signal #S to generate a second PWM signal #D. Following the comparison stage, a driver stage is performed, wherein the first driver 104a and a second driver 104b buffer the first PWM signal #U and second PWM signal #D to drive the speaker 106. The speaker 106 comprises a first end coupled to the first PWM signal #U, and a second end coupled to the second PWM signal #D. Hence, the first PWM signal #U and the second PWM signal #D jointly generate an audio output to be heard through the speaker 106.

Unlike the conventional class D architecture, the embodiment provides a detector 310 and a saw-tooth generator 320, whereby the saw-tooth signal #S is generated based on amplitude of the audio input signal V+. The detector 310 detects the amplitude of the audio input signal V+ to generate a control signal #ctrl, and the saw-tooth generator 320 adjusts a transition rate of the saw-tooth signal #S based on the control signal #ctrl.

Since the transition rate F_{SAW} determines the carrier frequency of harmonic distortions, it is preferable to provide a dynamic saw-tooth signal #S dependent on the amplitude of the audio input signal V+. When the amplitude of the audio input signal V+ is small, the magnitude of the side lobes 212 is negligible, so that the side lobes 212 do not cause significant influence even if the LPF curve 210 does not filtrate out the side lobes 212. Therefore, the saw-tooth signal #S can be configured with a lower transition rate F_{SAW} to economize the power consumption. Conversely, when the amplitude of the audio input signal V+ turns large, the side lobes 212 begin to emit EMI radiation that cannot be neglected. To prevent the unwanted EMI, the saw-tooth signal #S is adjusted to increase the carrier frequency, such that the side lobes 212 are shifted right towards the outer region of the LPF curve 210 and are filtrated out. Thus, power consumption may increase due to the switching power loss when increasing the transition rate F_{SAW}. Nevertheless, high power consumption will not be a problem when the amplitude of the audio input signal V+ is large.

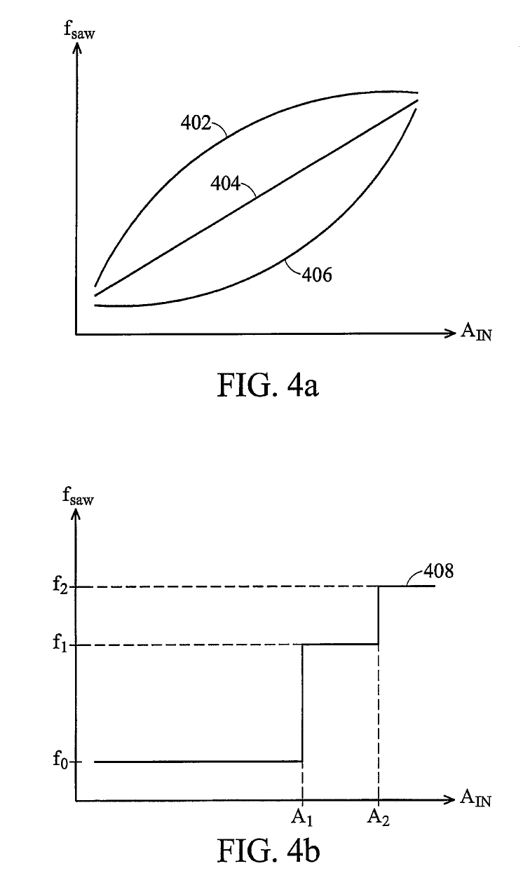

FIGS. 4a and 4b show embodiments of relationships between signal amplitude A_{IN} and transition rate F_{SAW}. In the embodiment, the relationship between the transition rate F_{SAW} of the saw-tooth signal #S and the signal amplitude A_{IN} of the audio input signal V+ may be a monotonic increasing function. There are various types of monotonic increasing functions. For example, the curve 402 shows a concave function, the curve 404 shows a linear function, and the curve 406 shows a convex function. The detector 310 may be implemented by using an analog to digital converter (ADC) with a lookup table to provide particular functions. Meanwhile, the saw-tooth signal #S is proportional to the signal amplitude A_{IN.}

FIG. 4b shows an alternative embodiment of the transition functions. The curve 408 shows that the relationship between the transition rate F_{SAW} and the signal amplitude A_{IN} may be a stepwise increasing function. For example, according to the curve 408, when the signal amplitude A_{IN} is below a first level A₁, the transition rate F_{SAW} is configured at frequency f₀. When the signal amplitude A_{IN} is between the first level A₁ and a second level A₂, the transition rate F_{SAW} is configured at frequency F₁. Furthermore, when the signal amplitude A_{IN} exceeds the second level A₂, the transition rate F_{SAW} is configured at frequency f₂. The level values A₁ and A₂ respective to the frequencies f₀, f₁ and f₂ are all programmable.

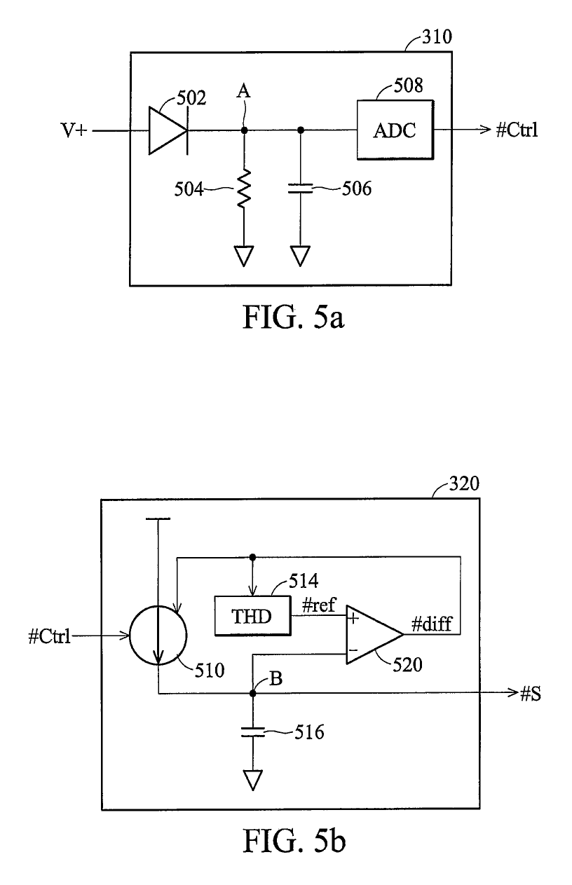

FIG. 5a shows an embodiment of a detector 310. Since the audio input signal A+ is a time varying signal, the detector 310 may sample the envelop of the audio input signal A+ to generate a digitized value as the control signal #ctrl. To detect the envelop, a diode 502 receives the audio input signal A+ at a P end, while its N end is coupled to a node A. A resistor 504 and a capacitor 506 are cascaded in parallel between the node A and a voltage ground. An ADC 508 then converts the voltage level on the node A into the control signal #ctrl. The ADC 508 may be a multi-bit ADC at a predetermined sampling rate, and the control signal #ctrl may be a multi-bit digital signal dedicated to control the saw-tooth generator 320.

FIG. 5b shows an embodiment of a saw-tooth generator 320. The saw-tooth generator 320 is designed to be controlled by the control signal #ctrl. Specifically, the transition rate F_{SAW} of the saw-tooth signal #S is dependent on a current, and the control signal #ctrl is adapted to adjust the current, which in turn adjusts the transition rate F_{SAW}. In the saw-tooth generator 320, a programmable current source 510 is deployed to generate the current. A capacitor 516 coupled to the programmable current source 510 and the voltage ground is driven by the current to generate the saw-tooth signal #S at a node B. A reference generator 514 functions as a boundary detector, generating a variable reference value to define an upper bound and a lower bound of the saw-tooth signal #S. An operational amplifier 520 is deployed to track the voltage on node B based on the reference value #ref, which is known as the saw-tooth signal #S. To implement a time varying saw-tooth signal #S, the operational amplifier 520 compares a present output saw-tooth signal #S and the reference value #ref to generate a difference signal #Diff, and the difference signal #Diff is further fed back to control the reference generator 514 and the programmable current source 510.

For example, the reference generator 514 may output a positive reference value #ref when the difference signal #Diff is positive. Meanwhile, in response to the positive difference signal #Diff, the programmable current source 510 may simultaneously output a current to charge the capacitor 516, such that the saw-tooth signal #S is continuously pulled up to approach the reference value #ref Conversely, when the difference signal #Diff is negative, the reference generator 514 outputs a negative reference value #ref while the programmable current source 510 stops supplying the current to the node B, such that the voltage level on the node B is discharged through the capacitor 516, rendering the saw-tooth signal #S to be continuously pulled down to approach the reference value #ref.

It is shown that when the control signal #ctrl is increased, the charging speed of the capacitor 516 is increased, so that the voltage level on node B would increase more rapidly, causing the transition rate F_{SAW} to increase. In the embodiment, the discharging speed of the capacitor 516 is not affected by the control signal #ctrl, however, the programmable current source 510 may be further modified to do so. The programmable current source 510 may be implemented by various known alternatives to achieve the programmable features, thus, the details are not limited in the invention.

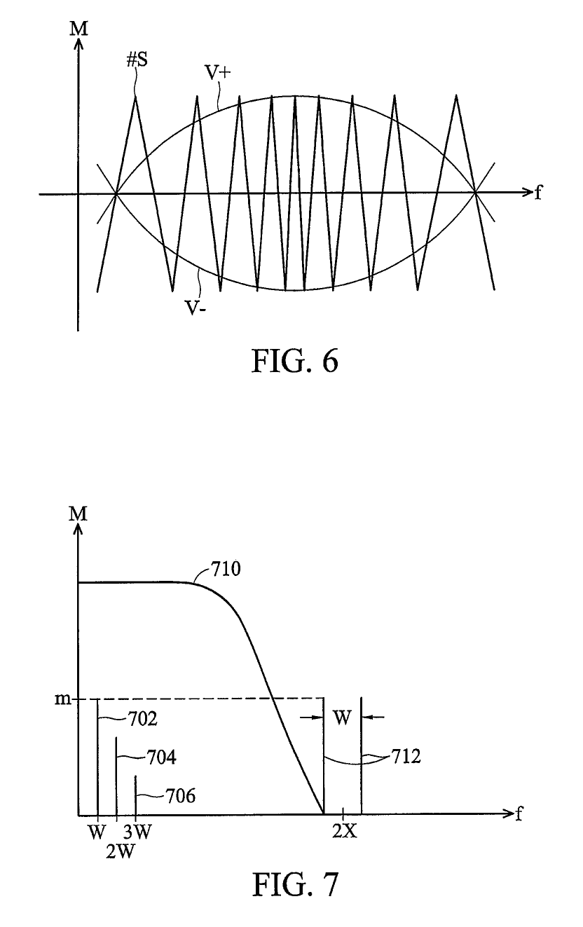

FIG. 6 shows waveforms of a saw-tooth signal #S and audio input signals V+ and V− according to the invention. The horizontal axis represents time, and the vertical axis represents magnitude. The V− is an inversion of the V+, forming a symmetric mirror with respect to the horizontal axis. It is shown that as the amplitude of audio input signal V+ increases, the saw-tooth signal #S varies more rapidly. As described, the variation of the transition rate F_{SAW} can be dependent on the transition functions as shown in FIGS. 4a and 4b. In FIG. 7, the frequency spectrum of a signal output from the speaker 106 is shown. Like FIG. 2, an in-band signal 702 represents the audio signal designated to be heard, operating at frequency w and having a magnitude m. Harmonic distortions 704 and 706 occur at frequencies 2w and 3w. A pair of side lobes 712 respectively occur at frequencies 2x+w and 2x−w, where the 2x is a second order carrier frequency. The carrier frequency x is increased when the amplitude of the audio input signal V+ increases, thus, the side lobes 712 are shifted right toward the effective filtration region of the LPF curve 710 and are thereby filtrated out.

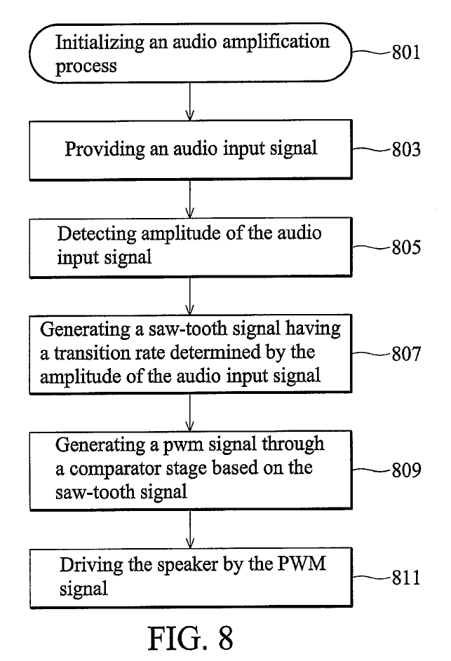

FIG. 8 is a flowchart of an audio amplification method according to the invention. In step 801, the digital speaking device 300 is initialized. In step 803, an audio input signal is provided to the digital speaking device 300. In step 805, the detector 310 detects amplitude of the audio input signal. In step 807, the saw-tooth generator 320 generates a saw-tooth signal with a transition rate based on the amplitude of the audio signal. In step 809, the audio input signal is converted into a Pulse Width Modulation (PWM) signal based on the saw-tooth signal. In step 811, the speaker is driven by the PWM signal to broadcast audio sounds. The embodiment of the invention successfully provides an adaptable saw-tooth generator 320 to balance the tradeoff between power consumption and signal qualities. Since no extra RC circuit is required, the structure is cost effective and feasible.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A switching audio amplifier for driving a speaker, comprising:
a comparison stage, comparing an audio input signal with a saw-tooth signal to generate a Pulse Width Modulation (PWM) signal;
a driver stage, coupled to the comparator, buffering the PWM signal to drive the speaker;
a detector, detecting an amplitude of the input signal to generate a control signal; and
a saw-tooth generator, coupled to the detector, adjusting a transition rate of the saw-tooth signal based on the control signal.

2. The switching audio amplifier as claimed in claim 1, wherein the comparison stage comprises:
a first comparator, comparing the audio input signal with the saw-tooth signal to generate a first PWM signal; and
a second comparator, comparing an inversion of the audio input signal with the saw-tooth signal to generate a second PWM signal.

3. The switching audio amplifier as claimed in claim 2, wherein the driver stage comprises:
a first driver, coupled to the first comparator, receiving the first PWM signal to drive a first end of the speaker; and
a second driver, couple to the second comparator, receiving the second PWM signal to drive a second end of the speaker.

4. The switching audio amplifier as claimed in claim 1, wherein the relationship between the transition rate of the saw-tooth signal and the amplitude of the audio input signal is a monotonic increasing function.

5. The switching audio amplifier as claimed in claim 1, wherein the relationship between the transition rate of the saw-tooth signal and the amplitude of the audio input signal is a stepwise increasing function.

6. The switching audio amplifier as claimed in claim 1, wherein the detector comprises:
a diode, comprising a P end coupled to the audio input signal, and a N end coupled to a first node;
a resistor, coupled to the first node and a voltage ground;
a capacitor, coupled to the first node and the voltage ground; and
an analog to digital converter (ADC), coupled to the first node, generating the control signal based on a voltage level of the first node.

7. The switching audio amplifier as claimed in claim 1, wherein the saw-tooth generator comprises:
a programmable current source for generating a current;
a capacitor, coupled to the programmable current source and the voltage ground, driven by the current to generate the saw-tooth signal;
a reference generator, generating a reference value based on a difference signal; and
an operational amplifier, comparing the saw-tooth signal and the reference value to generate the difference signal, wherein the programmable current source adjusts the current based on the control signal and the difference signal.

8. The switching audio amplifier as claimed in claim 7, wherein:
the reference generator outputs a positive reference value when the difference signal is positive; and
the reference generator outputs a negative reference value when the difference signal is negative.

9. The switching audio amplifier as claimed in claim 7, wherein:
the programmable current source is switched to a first mode when the difference signal is positive, such that the current charges the capacitor to generate the saw-tooth signal; and
the programmable current source is switched to a second mode when the difference signal is negative, such that the capacitor discharges to generate the saw-tooth signal.

10. A digital speaking device, comprising a switching audio amplifier and a speaker driven by the switching audio amplifier, wherein the switching audio amplifier comprises:
a comparison stage, comparing an audio input signal with a saw-tooth signal to generate a Pulse Width Modulation (PWM) signal;
a driver stage, coupled to the comparator, buffering the PWM signal to drive the speaker;
a detector, detecting an amplitude of the input signal to generate a control signal; and
a saw-tooth generator, coupled to the detector, adjusting a transition rate of the saw-tooth signal based on the control signal.

11. The digital speaking device as claimed in claim 10, wherein the comparison stage comprises:
a first comparator, comparing the audio input signal with the saw-tooth signal to generate a first PWM signal; and
a second comparator, comparing an inversion of the audio input signal with the saw-tooth signal to generate a second PWM signal.

12. The digital speaking device as claimed in claim 1 1, wherein the driver stage comprises:
a first driver, coupled to the first comparator, receiving the first PWM signal to drive a first end of the speaker; and
a second driver, couple to the second comparator, receiving the second PWM signal to drive a second end of the speaker.

13. The digital speaking device as claimed in claim 10, wherein the relationship between the transition rate of the saw-tooth signal and the amplitude of the audio input signal is a monotonic increasing function.

14. The digital speaking device as claimed in claim 10, wherein the relationship between the transition rate of the saw-tooth signal and the amplitude of the audio input signal is a stepwise increasing function.

15. The digital speaking device as claimed in claim 10, wherein the detector comprises:
a diode, comprising a P end coupled to the audio input signal, and a N end coupled to a first node;
a resistor, coupled to the first node and a voltage ground;
a capacitor, coupled to the first node and the voltage ground; and
an ADC, coupled to the first node, generating the control signal based on a voltage level of the first node.

16. The digital speaking device as claimed in claim 10, wherein the saw-tooth generator comprises:
a programmable current source for generating a current;
a capacitor, coupled to the programmable current source and the voltage ground, driven by the current to generate the saw-tooth signal;
a reference generator, generating a reference value based on a difference signal; and
a operational amplifier, comparing the saw-tooth signal and the reference value to generate the difference signal; wherein the programmable current source adjusts the current based on the control signal and the difference signal.

17. The digital speaking device as claimed in claim 16, wherein:
the reference generator outputs a positive reference value when the difference signal is positive; and
the reference generator outputs a negative reference value when the difference signal is negative.

18. The digital speaking device as claimed in claim 16, wherein:
the programmable current source is switched to a first mode when the difference signal is positive, such that the current charges the capacitor to generate the saw-tooth signal; and
the programmable current source is switched to a second mode when the difference signal is negative, such that the capacitor discharges to generate the saw-tooth signal.

19. An audio amplification method for driving a speaker, comprising:
providing an audio input signal;
detecting an amplitude of the audio input signal;
providing a saw-tooth signal with a transition rate determined based on the amplitude of the audio signal;
comparing the audio input signal with the saw-tooth signal to generate a modulation signal; and
driving the speaker by the modulation signal.

20. The audio amplification method as claimed in claim 19, wherein the relationship between the transition rate of the saw-tooth signal and the amplitude of the audio input signal is a monotonic increasing function.

21. The audio amplification method as claimed in claim 19, wherein the relationship between the transition rate of the saw-tooth signal and the amplitude of the audio input signal is a stepwise increasing function.

22. The audio amplification method as claimed in claim 19, wherein the step of detecting the amplitude of the audio signal comprises:
detecting an envelope of the audio signal; and
sampling the envelope at a first bit rate to generate a control signal.

23. The audio amplification method as claimed in claim 22, wherein the step of providing the saw-tooth signal comprises:
generating a current having a variable magnitude adjusted by the control signal;
driving a capacitor by the current to generate the saw-tooth signal;
generating a reference value based on a difference signal; and
providing an operational amplifier to track the saw-tooth signal based on a reference value and to generate the difference signal indicating difference of the saw-tooth signal and the reference value.

24. The audio amplification method as claimed in claim 23, wherein the step of generating the reference value comprises:
outputting a positive reference value when the difference signal is positive; and
outputting a negative reference value when the difference signal is negative.

25. The audio amplification method as claimed in claim 23, wherein the step of driving the capacitor comprises:
when the difference signal is positive, charging the capacitor by the current to generate the saw-tooth signal; and
when the difference signal is negative, discharging the capacitor to generate the saw-tooth signal.
